(19) United States
(12) Patent Application Publication
(10) Pub. No.: US 2013/0335009 A1
(43) Pub. Date: Dec. 19, 2013

(54) Inspection System, Charger/Discharger, and Inspection Method of Secondary Battery

(71) Applicant: HITACHI, LTD., Tokyo (JP)

(72) Inventors: Daisuke KATSUMATA, Fujisawa (JP); Chizu NOGUCHI, Nagano (JP); Toshiharu MIWA, Yokohama (JP); Takuo TAMURA, Yokohama (JP)

(73) Assignee: HITACHI, LTD., Tokyo (JP)

(21) Appl. No.: 13/768,089

(22) Filed: Feb. 15, 2013

(30) Foreign Application Priority Data
Jun. 19, 2012 (JP) 2012-137870

(51) Int. Cl. H02J 7/00; G01R 21/06

(52) U.S. Cl. CPC H02J 7/0042; G01R 21/06
USPC 320/107; 702/63

(57) ABSTRACT

An inspection system (a secondary battery anomaly detection system) has a ROM which stores data including information about a V-dQ/dV curve upon initial charge of a reference secondary battery. At inspection of a secondary battery, upon initial charge from a power supply, an anomaly detecting unit uses an amount of stored electricity calculated from a current value detected by a current detecting unit to calculate a dQ/dV actual measurement value, which is a ratio of a changed amount of the amount of stored electricity to a changed amount of a voltage value detected by a voltage detecting unit, compares the calculated value and the information about the V-dQ/dV curve to determine whether the calculated value corresponds to a feature point on the curve, and detects an anomaly of the secondary battery (incapability of long-term capacity reliability) when the calculated value does not correspond to the feature point on the curve.

### CROSS-REFERENCE TO RELATED APPLICATION

The present application claims priority from Japanese Patent Application No. 2012-137870 filed on Jun. 19, 2012 the content of which is hereby incorporated by reference into this application.

### TECHNICAL FIELD OF THE INVENTION

The present invention relates to technologies for second batteries such as lithium-ion secondary batteries.

### BACKGROUND OF THE INVENTION

A lithium-ion secondary battery has such a characteristic that, after repeated charge and discharge, oxidation of an electrolyte and destruction of a crystal structure on a cathode (positive electrode) side, and precipitation of metal lithium on an anode (negative electrode) side occur, thereby degrading the capacity of the battery. Also, in general, the capacity of the above-described battery may be quickly degraded depending on the manufacturing conditions of the lithium-ion secondary battery.

When the second battery with fast degradation in capacity is used, after the capacity is degraded, necessary power cannot be provided to a device using this secondary battery. For this reason, there is a need to provide a secondary battery with reliable long-term capacity (with small degradation in capacity) is needed to be provided by detecting and excluding this secondary battery with fast degradation in capacity at the time of manufacture (in a manufacturing stage).

Examples of existing technology regarding the secondary battery include Japanese Patent Application Laid-Open Publication No. 2010-257984 (Patent Document 1) and Japanese Patent Application Laid-Open Publication No. 2003-243046 (Patent Document 2).

Patent Document 1 (“SECONDARY BATTERY SYSTEM”) describes that “a secondary battery system capable of accurately detecting the state of the secondary battery system (such as the state of the secondary battery and an anomaly in the secondary battery system) is provided” etc.

Patent Document 2 (“METHOD FOR DETERMINING BATTERY WITH MALFUNCTION”) describes that “a method of determining a long-term discharge performance in a battery, in particular, a lithium/silver vanadium oxide battery, is provided” etc.

### SUMMARY OF THE INVENTION

Patent Document 1 discloses a system in which a feature point appearing on a Q-dV/dQ curve representing a relation between a value of an amount of stored electricity Q and a value of dV/dQ, which is a ratio of a changed amount dV of a voltage V with respect to a changed amount dQ of the amount of stored electricity Q to detect a degradation condition of the secondary battery in operation (in a non-manufacture stage). However, no disclosure is made as to, for example, a method of obtaining (detecting) long-term capacity reliability at a manufacturing stage of the secondary battery.

Patent Document 2 describes that a method of determining a long-term capacity (long-term discharge performance) (a guide for reliable long-term discharge performance) by analyzing and characterizing the waveform of an initial pulse voltage is provided. However, in this method, a process of inspecting an initial pulse voltage has to be added, and therefore an additional inspection device and inspection time are required, thereby increasing cost.

In view of these points, a main preferred aim of the present invention is to provide technology capable of obtaining a secondary battery allowing long-term capacity reliability to be ensured at a manufacturing stage of a secondary battery (a secondary battery with small degradation in capacity), in other words, technology capable of detecting and excluding a secondary battery without long-term capacity reliability (a secondary battery with fast degradation in capacity), and also technology achievable at low cost without requiring any additional inspection process, inspection device, inspection time, and others.

To achieve the preferred aim described above, a typical aspect of the present invention provides a system (an information processing system and device), method, and others of inspecting (detecting an anomaly in) a secondary battery such as a lithium-ion secondary battery, and has the structures described below.

An inspection system (and its corresponding inspection method) of the present aspect includes a unit (and its corresponding inspecting process) of using a feature point appearing on a V-dQ/dV curve indicating a relation between a voltage V upon initial charge and a dQ/dV value, which is a ratio of a changed quantity dQ of an amount of stored electricity Q with respect to a changed amount dV of the voltage V at a manufacturing stage of a secondary battery to determine long-term capacity reliability (long-term capacity degradation) and detecting and excluding an anomaly.

An inspection system of secondary battery (an anomaly detection system of secondary battery) of the present aspect includes a voltage detecting unit, a current detecting unit, an anomaly detecting unit, and a storage unit, and a first secondary battery to be inspected is connected to the voltage detecting unit, the current detecting unit, and a power supply. The storage unit previously stores data of characteristics of a second secondary battery to be a reference for anomaly detection. The data of the characteristics contains information about a V-dQ/dV curve representing a relation between a voltage V and a dQ/dV value, which is a ratio of a changed amount dQ of an amount of stored electricity Q calculated from a current I with respect to a changed amount dV of the voltage V upon initial charge of the second secondary battery for reference. In the present inspection system, upon inspection of the first secondary battery, when initial charge is performed on the first secondary battery from the power supply, the voltage detecting unit detects a voltage value V of the first secondary battery, and the current detecting means detects a current value I of the first secondary battery. Then, the anomaly detecting means uses an amount of stored electricity Q calculated from the current value I to calculate a dQ/dV actual measurement value, which is a ratio of a changed amount dQ of the amount of stored electricity Q with respect to a changed amount dV of the voltage value V, compares the dQ/dV actual measurement value and the information about the V-dQ/dV curve to determine whether the dQ/dV actual measurement value corresponds to a feature point on the curve, and detects an anomaly indicating that long-term capacity reliability of the first secondary battery cannot be ensured when the dQ/dV actual measurement value does not correspond to the feature point.

According to the typical aspect of the present invention, a secondary battery allowing long-term capacity reliability to be ensured at a manufacturing stage of a secondary battery (a secondary battery with small degradation in capacity) can be obtained. In other words, a secondary battery without long-term capacity reliability (with fast degradation in capacity) can be detected and excluded. Also, this can be achieved at low cost without requiring any additional inspection process, inspection device, inspection time, and others.

### BRIEF DESCRIPTIONS OF THE DRAWINGS

FIG. 1 is a diagram illustrating structure of a secondary battery inspection system according to a first embodiment of the present invention;

FIG. 2 is a diagram illustrating structure of an inspection system (including a secondary battery anomaly detecting charger/discharger) according to a second embodiment;

FIG. 3 is a diagram illustrating the structure of a secondary battery anomaly detecting unit of an inspection system according to a third embodiment;

FIG. 4 is a diagram illustrating a V-dQ/dV curve (an example of data of reference characteristics) upon initial charge of a secondary battery according to an embodiment (each embodiment);

FIG. 5 is a diagram schematically illustrating a specific process of manufacturing a lithium ion secondary battery according to an embodiment;

FIG. 6 is a diagram illustrating an example of data of charge characteristics (stored Q-V) upon initial charge of the secondary battery (an inspection target) according to an embodiment;

FIG. 7 is a diagram illustrating an example of a V-dQ/dV curve (actual measurement) upon initial charge of the secondary battery (an inspection target) according to an embodiment;

FIG. 8 is a diagram illustrating results of a cycle test for obtaining data of reference characteristics (capacity retaining ratios of second batteries of respective groups) according to an embodiment;

FIG. 9 is a diagram illustrating a V-dQ/dV curve upon initial charge of a first group;

FIG. 10 is a diagram illustrating a V-dQ/dV curve upon initial charge of a second group;

FIG. 11 is a diagram illustrating a V-dQ/dV curve upon initial charge of a third group;

FIG. 12 is a diagram illustrating a V-dQ/dV curve upon initial charge of a fourth group;

FIG. 13 is a diagram of a V-dQ/dV curve (L) after a cycle test;

FIG. 14 is a diagram of a process flow (a first flow) of inspection (anomaly detection) in an inspection system (its corresponding inspection method) of a fourth embodiment;

FIG. 15 is a diagram of a process flow (a second flow) of inspection (anomaly detection) in an inspection system (its corresponding inspection method) of a fifth embodiment; and

FIG. 16 is a diagram for supplemental description of a determination at step S106.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

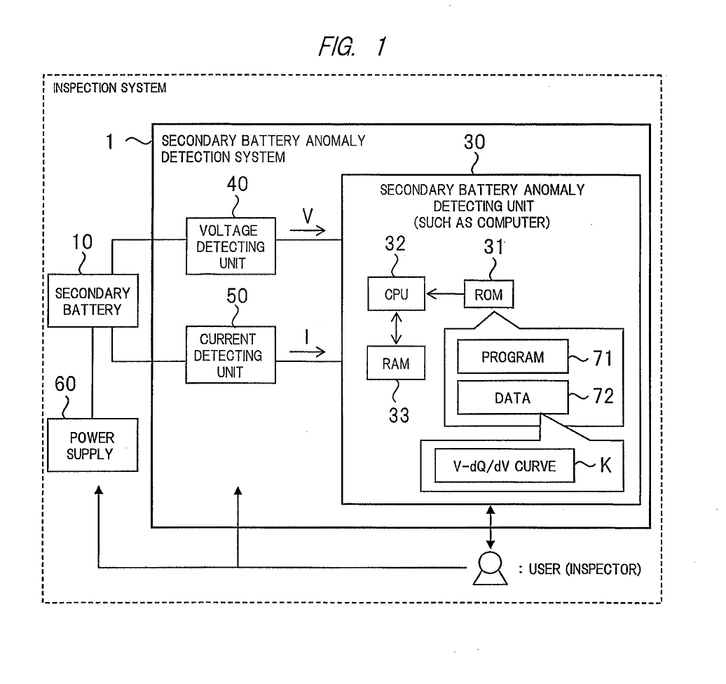

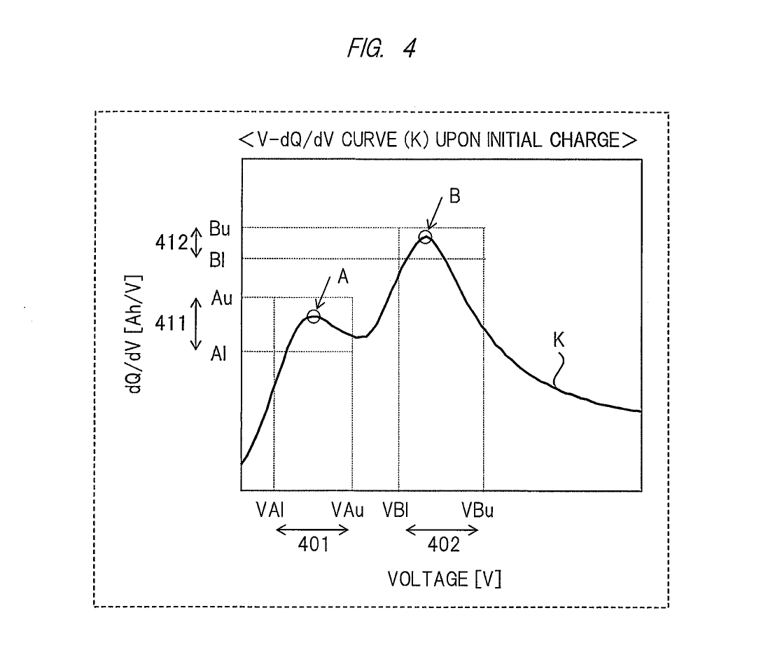

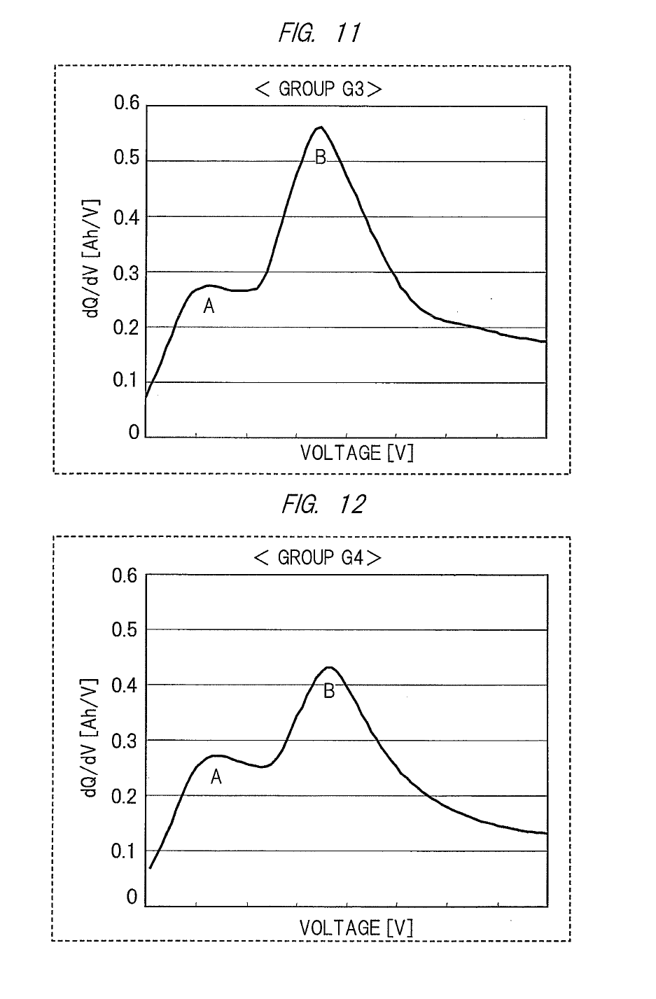

A secondary battery inspection system and its corresponding inspection method of a first embodiment are described by using FIG. 1, FIGS. 4 to 13, and others.

[System Structure]

FIG. 1 illustrates an entire structure of a second battery inspection system of the first embodiment. The present inspection system includes an anomaly detection system (a secondary battery anomaly detection system) 1, a secondary battery 10, and a power supply 60 connected to one another. The anomaly detection system 1 includes a voltage detecting unit 40, a current detecting unit 50, and an anomaly detecting unit (a secondary battery anomaly detecting unit) 30. The secondary battery 10 is a single lithium-ion secondary battery to be inspected. Upon inspection, the secondary battery 10 to be inspected is connected to the voltage detecting unit 40, the current detecting unit 50, and the power supply 60. The voltage detecting unit 40 and the current detecting unit 50 are connected to the secondary battery anomaly detecting unit 30.

The power supply 60 is a power supply device capable of performing a charge/discharge operation on the secondary battery 10 to be connected (known art). The charge/discharge operation by the power supply 60 can be performed with operation (or automatic control, which will be described below) by a user (an inspector).

The anomaly detecting unit 30 is configured of a computer (calculator) in the first embodiment, including known elements such as a ROM 31, a CPU 32, and a RAM 33. In the ROM 31 (this may be another storage unit), a program 71 (a program for causing an inspection process to be performed) and data 72 (various data information regarding the inspection process) are stored. By reading the program 71 and the data 72 in the ROM 31 and using the RAM 33 to perform program processing, the CPU 32 performs an inspection process on the secondary battery 10.

A user (an inspector) operates and uses the present inspection system (the anomaly detection system 1 including the anomaly detecting unit 30) to perform an inspection (including anomaly detection) on the secondary battery 10. Although not illustrated, the anomaly detecting unit 30 includes an input device, an output device, and a user interface function. The user interface function includes, for example, a function of displaying various information (such as an inspection menu, setting values, and result information about an inspection including an anomaly signal (anomaly detection)) upon inspection on a display screen and accepting an instruction input and others from the user.

The voltage detecting unit 40 detects a voltage V (a voltage across terminals) of the secondary battery 10 and provides that voltage V (its value and information) to the anomaly detecting unit 30.

The current detecting unit 50 detects a current I flowing through the secondary battery 10 and provides that current I (its value and information) to the anomaly detecting unit 30.

The anomaly detecting unit 30 uses the voltage value V inputted from the voltage detecting unit 40 and the current value I inputted from the current detecting unit 50 to perform an inspection (including anomaly detection) on the secondary battery 10 by program processing and outputs the result (such as an anomaly signal when anomaly is detected) to the user.

The anomaly detecting unit 30 calculates a dQ/dV value (an actual measurement value), which is a ratio of a changed amount dQ of an amount of stored electricity Q with respect to a changed amount dV of the voltage V when the voltage V of the secondary battery 10 is changed upon initial charge of the secondary battery 10. In other words, the amount of stored electricity Q of the secondary battery 10 is differentiated with respect to the corresponding voltage V to calculate a dQ/dV value. Specifically, while the voltage V and the current I (the amount of stored electricity Q) is obtained at each predetermined time upon charge/discharge (particularly upon initial discharge) of the secondary battery 10, the changed amount dV of the voltage V and the changed amount dQ of the amount of stored electricity Q are calculated for each time and, based on these, a dQ/dV value at each predetermined time is calculated.

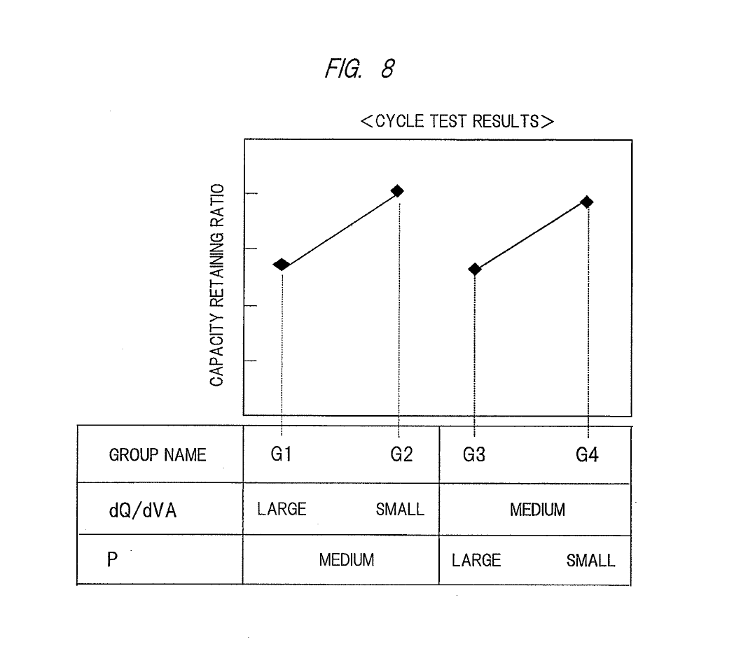

The data 72 stored in the ROM 31 includes information about a V-dQ/dV curve (K) (FIG. 4, which will be described further below). In the present inspection system, the information about the V-dQ/dV curve (K) upon initial charge in a reference secondary battery with long-term capacity reliability (the information includes a range of feature points) is stored in advance (at least before inspection) as characteristic data for reference (for comparison). The reference secondary battery is a secondary battery with a high capacity retaining ratio and ensured long-term capacity reliability as a result of a cycle test, which will be described further below (such as FIG. 8).

Note that the respective units (such as the anomaly detecting unit 30, voltage detecting unit 40, current detecting unit 50, and power supply 60) of FIG. 1 may be achieved (implemented) by various means. For example, the anomaly detecting unit 30 is not restricted to program processing of a general-purpose computer, but may be achieved by a circuit of a dedicated IC chip or the like. The voltage detecting unit 40 and current detecting unit 50 may be each achieved by an existing detecting device. The anomaly detecting unit 30 may be achieved by an existing charger/discharger.

Prior to describing details of processes in the first embodiment, examples of system structures of other embodiments (2, 3) will be described below. The details of processes are generally common among these embodiments.

### Second Embodiment

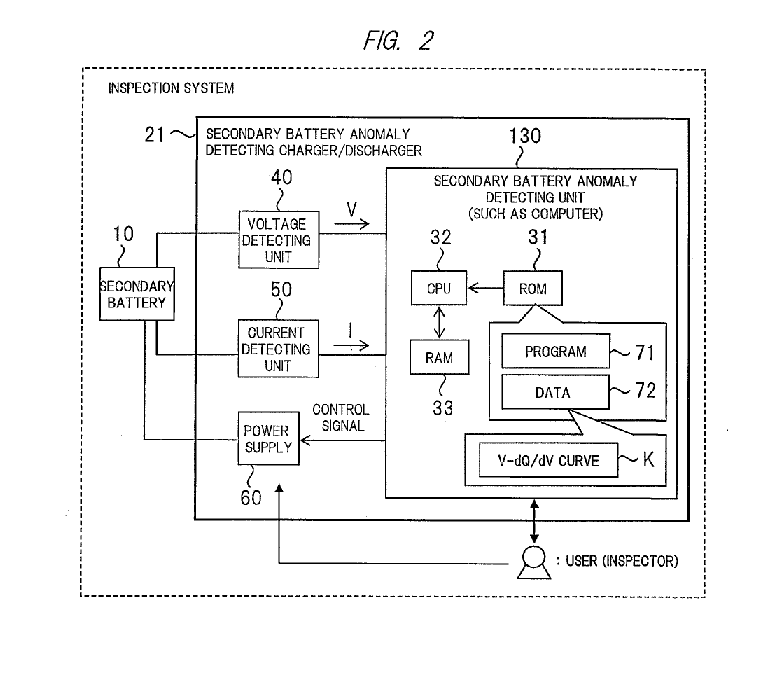

FIG. 2 illustrates an example of structure of a charger/discharger 21 (a charger/discharger for detecting anomaly of secondary battery) including a function of detecting an anomaly in a secondary battery as an inspection system of a second embodiment. The charger/discharger 21 includes the function of detecting an anomaly in the secondary battery 10 (such as a voltage detecting unit 40, a current detecting unit 50, and an anomaly detecting unit 130) similar to that of the first embodiment. Furthermore, the charger/discharger 21 has incorporated therein a power supply 60 capable of a charge/discharge operation on the secondary battery 10, allowing control (control of charge/discharge operation) from the anomaly detecting unit 130 to the power supply 60. As described above, the secondary battery 10 is connected to each unit (the voltage detecting unit 40, current detecting unit 50, and power supply 60).

As with the anomaly detecting unit 30 of the first embodiment, the anomaly detecting unit 130 of the second embodiment is achieved by program processing of a computer. Furthermore, the anomaly detecting unit 130 of the second embodiment has a function of automatically controlling a charge/discharge operation (for example, the start and end of initial discharge) on the secondary battery 10 from the power supply 50 by providing a control signal to the power supply 60 as required. Note that, when the structure does not include this control function, as with the first embodiment, the power supply 60 is operated by the user. The power supply 60 charges the secondary battery 10 by applying a current or voltage to the secondary battery 10 based on the control signal from the anomaly detecting unit 130.

### Third Embodiment

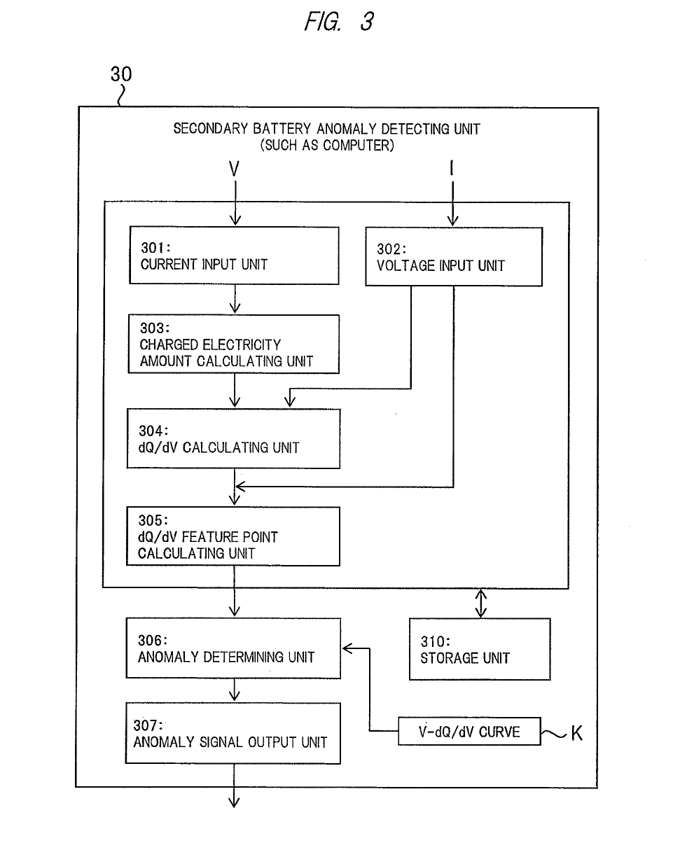

FIG. 3 is an example of a detailed structure of the anomaly detecting unit 30 as an inspection system of a third embodiment. This anomaly detecting unit 30 includes a current input unit 301, a voltage input unit 302, a charged electricity amount calculating unit 303, a dQ/dV calculating unit 304, a dQ/dV feature point calculating unit 305, an anomaly determining unit 306, an anomaly signal output unit 307, a storage unit 310, and others. These units may be each configured as a program module or may be configured of a circuit unit or the like. Also, the structure is such that data information to be processed at each unit (such as 301 to 305) is stored in the storage unit 310 as appropriate. A general outline of the process of the anomaly detecting unit 30 is as follows.

The anomaly detecting unit 30 receives inputs of the voltage V of the secondary battery 10 detected by the voltage detecting unit 40 and the current I of the secondary battery 10 detected by the current detecting unit 50 upon initial charge of the secondary battery 10 to be inspected. For example, the current input unit 301 receives an input of (acquires) the current value I at each predetermined time T and, at timings synchronous therewith (or at timings synchronous with a current accumulating process at the charged electricity amount calculating unit 303 described below), the voltage input unit 302 receives an input of (acquires) the voltage value V. T is a unit on digital processing.

The charged electricity amount calculating unit 303 accumulates the current value I based on the current value I (at each T) from the current input unit 301 to calculate an amount of stored electricity Q (an electrical storage capacity) at each T from a charged electricity amount or a discharged electricity amount of the secondary battery 10.

The dQ/dV calculating unit 304 calculates a dQ/dV actual measurement value (at each T) based on the voltage value V (at each T) from the voltage input unit 302 and the amount of stored electricity Q (at each T) from the charged electricity amount calculating unit 303. Also, the dQ/dV calculating unit 304 may create, as required, a V-dQ/dV curve (for inspection, which is different from K) at a real-time basis based on the dQ/dV actual measurement value at each T (this corresponds to a fifth embodiment, which will be described further below).

The dQ/dV feature point calculating unit 305 calculates a feature point (for inspection) based on the voltage value V described above and the dQ/dV actual measurement value from the dQ/dV calculating unit 304.

The anomaly determining unit 306 makes a determination and detection by using and comparing the feature point (for inspection) from the dQ/dV feature point calculating unit 305 and the information (the range of the feature points) about the V-dQ/dV curve (K) in reference characteristics. That is, the anomaly determining unit 306 determines whether the feature point for inspection (the dQ/dV actual measurement value) corresponds to the range of the feature points of the V-dQ/dV curve (K), and makes a determination (detection) as normal (i.e., long-term capacity reliability can be ensured) when the feature point corresponds to the range and as anomaly (i.e., long-term capacity reliability cannot be ensured) when the feature point does not correspond to the range. For example, when the feature point for inspection exceeds the reference range, it is determined that long-term capacity reliability cannot be ensured (anomaly).

Then, when a determination (detection) is made as anomaly, the anomaly signal output unit 307 outputs an anomaly signal indicating that long-term capacity reliability of the secondary battery 10 cannot be ensured to the user, thereby prompting the user to exclude the secondary battery 10.

An example of detailed processes in the first embodiment (similarly applicable to each embodiment) will be described below.

[V-dQ/dV Curve (K)]

FIG. 4 illustrates a V-dQ/dV curve (K) upon initial charge of the reference secondary battery as an example of data of reference characteristics (for comparison) in each embodiment. The horizontal axis represents voltage [V], and the vertical axis represents a dQ/dV value [Ah/V]. The data 72 including the information of this curve K is stored in advance in the inspection system (the ROM 31). As the reference secondary battery, a secondary battery with a high capacity retaining ratio and ensured long-term capacity reliability as a result of a cycle test, which will be described further below (such as FIG. 8), is used.

In the curve K of FIG. 4, A and B represent two feature points (maximum points). Also, a range (401) of the voltage V from VAl to VAu and a range (411) of the dQ/dV value from Al to Au where the feature point A appears are illustrated. Furthermore, a range (402) of the voltage V from VBl to VBu and a range (412) of the dQ/dV value from Bl to Bu where the feature point B appears are depicted. Information about the ranges of the dQ/dV values and the voltage values V regarding the feature points (A, B) on the curve K is also included in the data 72. At inspection, the anomaly detecting unit 30 compares an actual measurement value (a dQ/dV value) obtained upon initial charge of the target secondary battery 10 with the ranges (described above) of the feature points A and B on this curve K, thereby making a determination and detection as anomaly (long-term capacity reliability).

[Secondary Battery Manufacturing Process]

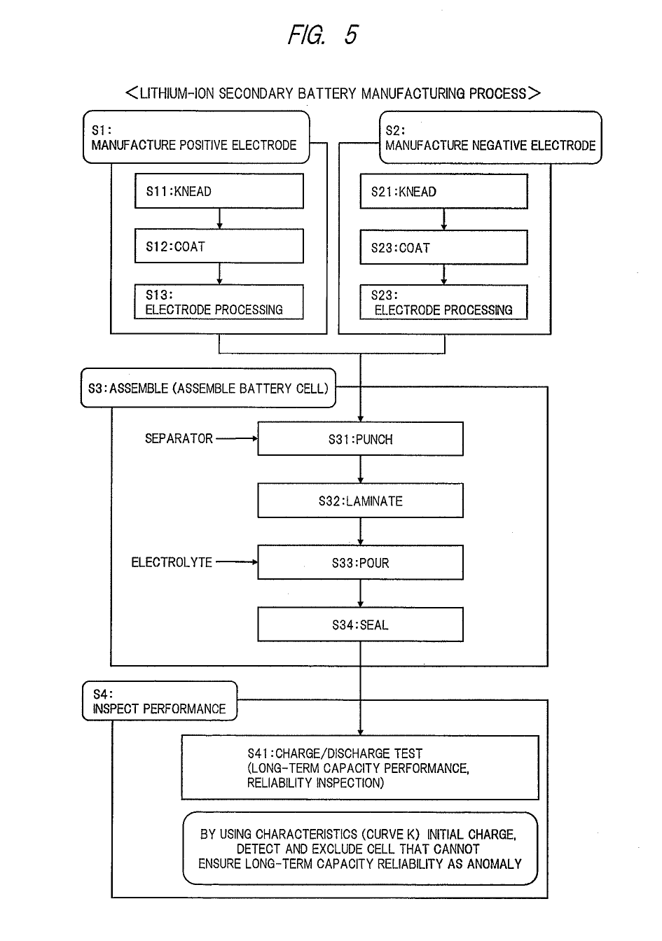

FIG. 5 illustrates a specific conventional and general process of manufacturing a lithium-ion secondary battery. This is similarly applied to the process of manufacturing the secondary battery 10 to be inspected in the present embodiment. In particular, in the inspection method of the present embodiment, a characteristic process step (an anomaly detection step using characteristics (curve) upon initial charge) is included in a charge/discharge test (an inspection regarding long-term capacity performance and reliability) (S41) at a performance inspection process (S4).

The manufacturing process of FIG. 5 broadly includes S1: positive electrode manufacturing process; S2: negative electrode manufacturing process; S3: assembling process (battery cell assembling process); and S4: performance inspecting process. S1 and others each represent a process (or step).

S1 and S2 include a kneading process (S11, S21), a coating process (S12, S22), and an electrode processing process (S13, S23). Various materials as cathode and anode materials are mixed in the kneading process (S11, S21). In the coating process (S12, S22), a metal foil on a roll is coated with the kneaded materials. In the electrode processing process (S13, S23), the coated part is subjected to processing such as compression, thereby creating positive and negative electrode rolls.

The assembling process at S3 has a punching process (S31), a laminating process (S32), a pouring process (S33), and a sealing process (S34). At S31, the positive and anode rolls are each cut out (punched) to an electrode sheet of a predetermined size by using a separator. At S32, a plurality of cathode/anode electrode sheets are laminated. Then at S33, an electrolyte is infused (poured). At S34, these parts are hermetically closed (sealed) with a laminate film. In this manner, a secondary battery cell is obtained.

The performance inspecting process at S4 has a charge/discharge test (a long-term capacity performance and reliability inspection) process at S41. In this process at S41, the secondary battery cell created in the assembling process at S3 is repeatedly charged and discharged (a charge/discharge test) to perform an inspection regarding performance and reliability of this cell. For example, the capacity and voltage and the current and voltage at the time of charge or discharge are inspected.

In the inspection method of the present embodiment, an inspection (anomaly detection) is performed in the performance inspecting process of S4 by using the inspection system of the present embodiment (such as FIG. 1) and in the charge/discharge test (long-term capacity performance and reliability inspection) process of S41 by using the characteristics (the V-dQ/dV curve) upon initial charge. That is, a cell (secondary battery 10) with long-term capacity reliability not ensured is detected as an anomaly.

[Initial Charge]

A significant feature of the present embodiment is that the characteristics (curve) upon initial charge are used to determine (detect) an anomaly. Initial charge refers to charge for the first time immediately after manufacture of the secondary battery 10. In the manufacturing process of FIG. 5, after the secondary battery (cell) is assembled in the assembling process (S3), a charge/discharge test (an inspection regarding long-term capacity performance and reliability) is performed (S41), and the initial charge refers to the charge for the first time at this moment.

At this initial charge, a coating is formed on the electrode surface of the cell (the secondary battery 10). It is known that the long-term capacity of the cell (the secondary battery 10) is changed according to the degree of formation of the coating occurring in this initial charge. At the second time charge and onward, this coating formation reaction is decreased.

[Characteristics Upon Initial Charge at Inspection]

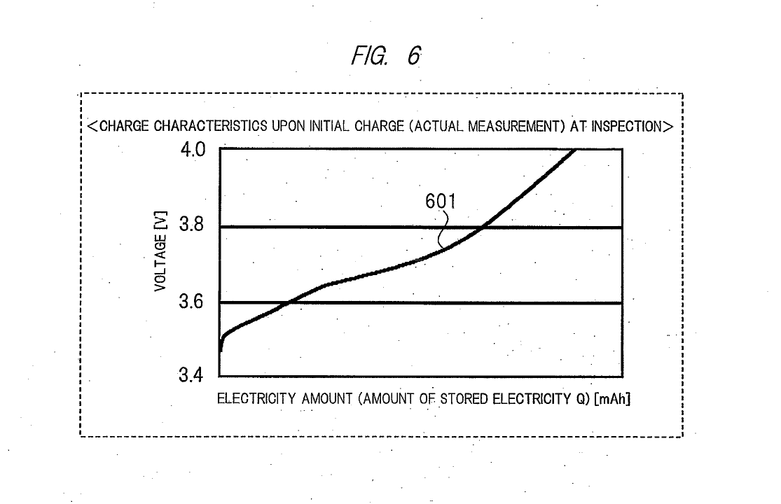

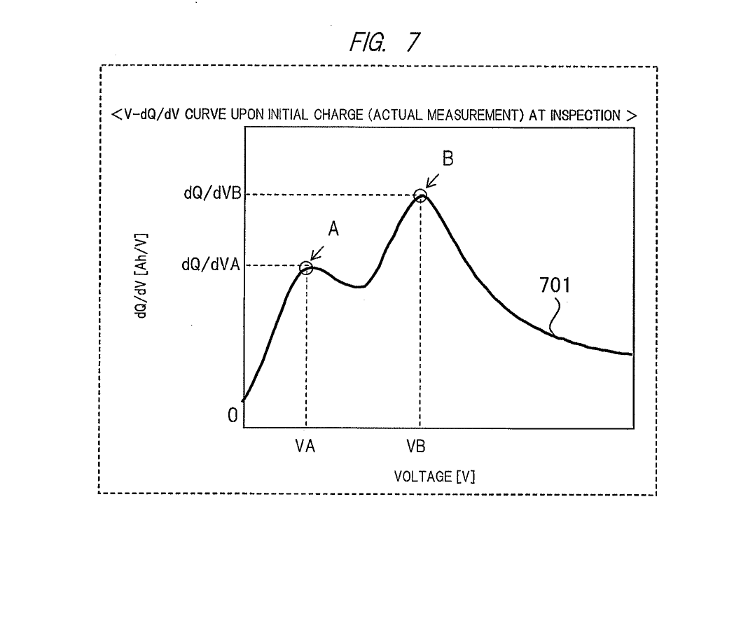

Next, an example of data of the characteristics upon initial charge (actual measurement) at inspection of the secondary battery 10 in the inspection method and the inspection system is described with reference to FIGS. 6 and 7.

FIG. 6 illustrates an example of data of charge characteristics obtained upon initial charge of the secondary battery 10 to be inspected. The horizontal axis represents amount of stored electricity Q (electricity amount [mVh]), the vertical axis represents voltage V (voltage [V]), and a function (curve) (601) indicates a relation of Q and V.

FIG. 7 illustrates a V-dQ/dV curve (701) indicating a relation between the voltage V and the dQ/dV value (actual measurement value) upon initial charge of the secondary battery 10 to be inspected (which is different from the reference curve K). The V-dQ/dV curve (701) of FIG. 7 is obtained by differentiating the amount of stored electricity Q with its corresponding voltage V for the function (601) between the amount of stored electricity Q and the voltage V of FIG. 6. Specifically, when the curve (601) of FIG. 6 is created, as described above, based on the amount of stored electricity Q and the voltage V obtained at each predetermined time T (one second, for example), a dQ/dV value is calculated at each T from the changed amount dV of the voltage V and the changed amount dQ of the amount of stored electricity Q. Then, a V-dQ/dV curve indicating a relation between this dQ/dV value and the voltage V is created as depicted in FIG. 7 (701).

In FIG. 7, in the V-dQ/dV curve (701), as with the reference curve K of FIG. 4, a plurality of (two) feature points such as feature points A and B (maximum points) appear. Note that the voltage value of the feature point A is represented by VA, the voltage value of the feature point B is represented by VB, the dQ/dV value of the feature point A is represented by dQ/dVA, and the dQ/dV value of the feature point B is represented by dQ/dVB. These feature points are considered to reflect the degree of coating formation as described above, and it is known that long-term capacity of the secondary battery 10 is changed according to the degree of formation of the coating occurring upon initial charge. By using this dQ/dV value upon initial charge, as with the V-dQ/dV curve (K) of FIG. 4, a reliable guide regarding long-term capacity of the secondary battery 10 (characteristics as a reference allowing long-term capacity reliability and information for comparison at anomaly detection) can be obtained. The procedure of a specific test or the like for obtaining the data (curve K) of the reference characteristics is as follows.

[Cycle Test]

In the inspection method and the inspection system of the present embodiment, by a cycle test (also called a cycle degradation test or a repeated charge/discharge test) in advance (at least before inspection) using a reference secondary battery, data of the reference characteristics (the V-dQ/dV curve (K)) is obtained and stored in the inspection system (the ROM 31) as described above.

A plurality of secondary batteries (reference secondary batteries) with different dQ/dV values at the feature points (the maximum points) upon initial charge as in the example of FIG. 7 were prepared, and a cycle degradation test (a repeated charge/discharge test) was performed.

FIG. 8 illustrates results of the cycle test of the secondary battery for obtaining the data of the reference characteristics (the capacity retaining ratios of secondary batteries of respective groups). The prepared plurality of secondary batteries were divided into four groups (G1 to G4) depending on the magnitude of the dQ/dV values of the feature points A and B and others as illustrated. These groups (G1 to G4) were classified as illustrated, with criteria of large/medium/small (a relative value among the prepared batteries) of the dQ/dV value (dQ/dVA) of the feature point A as in FIG. 7 and criteria of large/medium/small (a relative value among the prepared batteries) of a value P obtained from Equation 1 below.

P=a1×(dQ/dVB)+a2×(dQ/dVA) Equation 1

The value P is a value obtained by adding the dQ/dV value of the feature point A (maximum point) (dQ/dVA) and the dQ/dV value of a feature point B (maximum point) (dQ/dVB) together using coefficients a1 and a2.

Of the four groups in FIG. 8, the first group G1 includes a battery with a large dQ/dV value of the feature point A (maximum point) (dQ/dVA) and a medium P value; the second group G2 includes a battery with a small dQ/dVA value and a medium P value; the third group G3 includes a battery with a medium dQ/dVA value and a large P value; and the fourth group G4 includes a battery with a medium dQ/dVA value and a small P value.

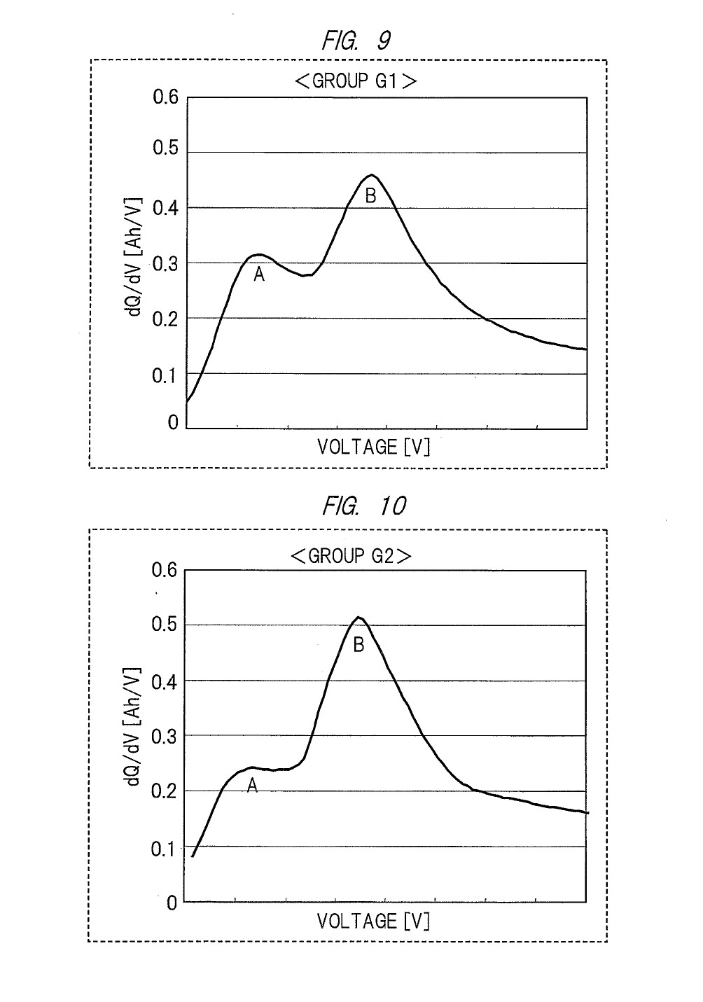

FIGS. 9 to 12 illustrate V-dQ/dV curves of the groups G1 to G4 upon initial charge, respectively.

Next, cycle charge/discharge was performed for each of the groups G1 to G4. Specifically, by a charge upper-limit voltage value being set at 4.2 V and a discharge lower-limit voltage value being set at 3.5 V, charge/discharge was performed for 300 cycles with a current value of 1C. Here, 1C means a current amount enough for discharging (charging) the entire capacity of a battery for one hour.

FIG. 8 illustrates capacity retaining ratios (ratios of capacity after a cycle degradation test with respect to initial capacity) in the respective groups G1 to G4 after the cycle charge/discharge. These capacity retaining ratios correspond to long-term capacity reliability (a degree of the ability to ensure the reliability) of the secondary battery. It can be found that the capacity retaining ratios vary depending on the group. In the example of FIG. 8, it can be found that the capacity retaining ratios of the groups G2 and G4 are higher than those of the groups G1 and G3.

In the inspection method and inspection system of the present embodiment, as a result of the test as described above, the characteristics (the V-dQ/dV curve) of the secondary battery (for example, the group G2 or G4) with a high capacity retaining ratio are used. For example, the one with a capacity retaining ratio higher than a predetermined threshold is selected for use.

By previously performing a cycle test using the reference secondary battery at the time of the performance inspecting process (S4) of FIG. 5 described above (at the charge/discharge test (S41)) and determining the capacity retaining ratio, data of the reference characteristics (the curve K) can be obtained. Then, separately, at the time of inspection of the secondary battery 10, the actual measurement value of the secondary battery 10 to be inspected upon initial charge is compared at S4 (S41) with the reference characteristics (the curve K). In this manner, the target can be detected as anomaly (the secondary battery 10 with long-term capacity reliability not ensured).

[Characteristics after Cycle Test]

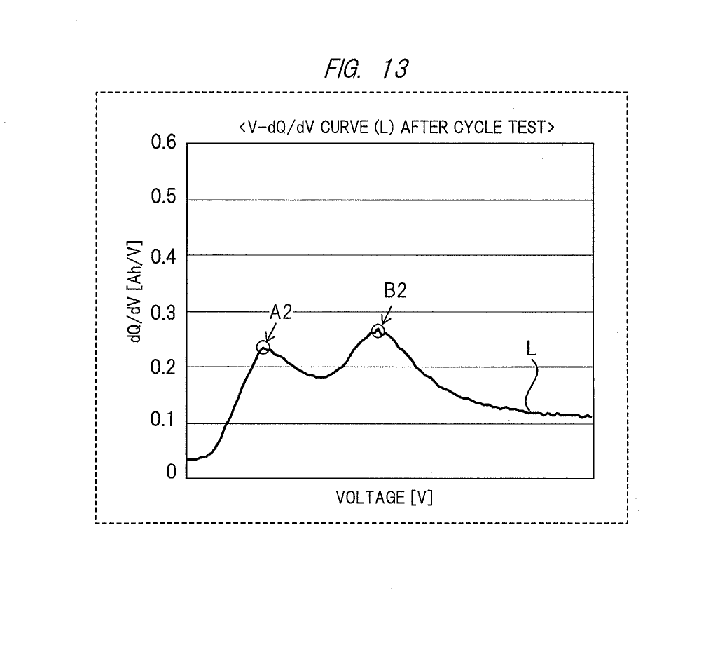

Also, FIG. 13 illustrates a V-dQ/dV curve (L) after the cycle test as described above (after charge/discharge has been performed many times) for comparison and description. In this V-dQ/dV curve (L), it can be found that dQ/dV values at its feature points A2 and B2 (maximum points) are smaller than those upon initial charge described above. Furthermore, at the feature points A2 and B2 (maximum points) of this V-dQ/dV curve (L), differences among the first to fourth groups (the secondary batteries with different degree of long-term capacity reliability) are difficult to find.

As such, it can be found that it is effective not to use the data of the characteristics of the secondary batter after repeated charge/discharge for a plurality of times (in operation or in actual use) but to use the information about the V-dQ/dV curve (K) (its feature points) upon initial charge at the manufacturing state.

### Fourth Embodiment

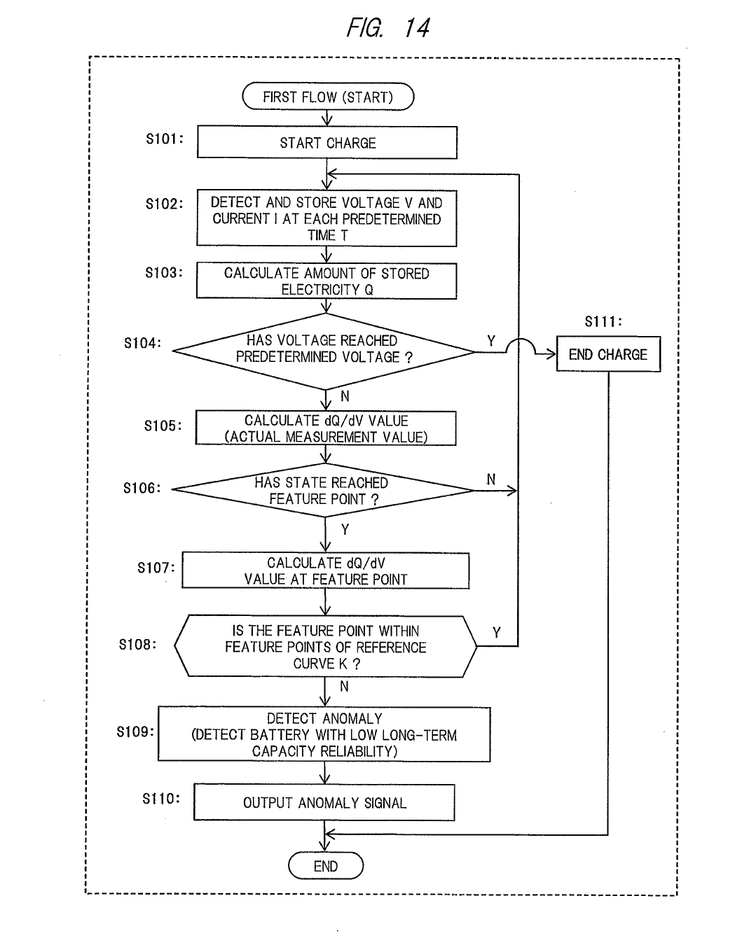

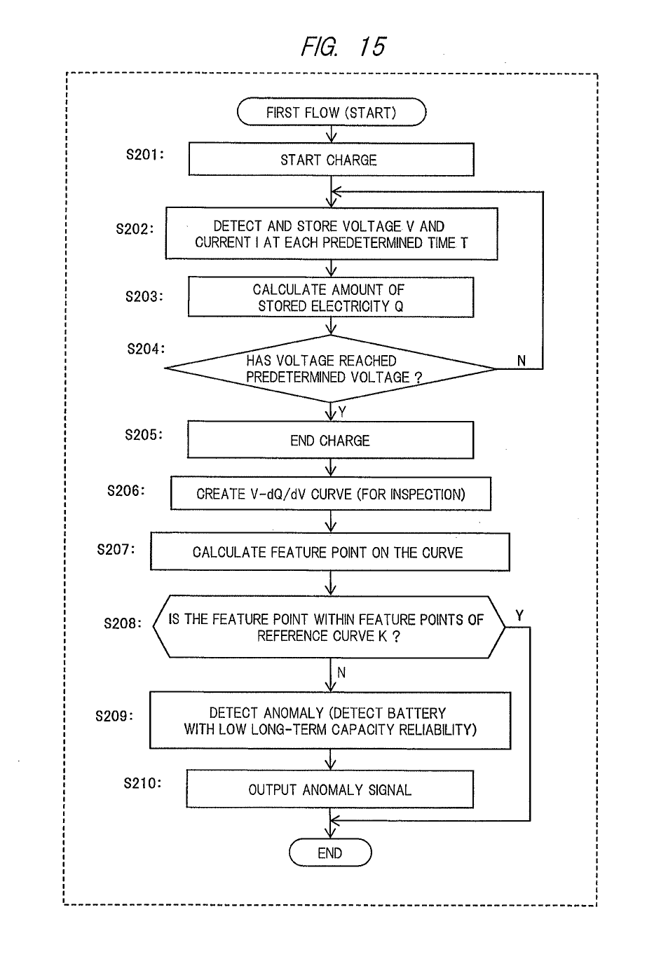

Next, an inspection method and an inspection system according to a fourth embodiment are described with reference to FIG. 14. FIG. 14 illustrates a process flow (a first flow) of detecting a secondary battery 10 with long-term capacity reliability not ensured (anomaly) in the fourth embodiment. The fourth embodiment has a basic structure similar to those of the first embodiment and others (such as FIG. 1). A different structure is such that, processes of FIG. 14 are performed with program processing at the anomaly detecting unit 30 based on, for example, a user operation, at the time of inspection (S4 in FIG. 5), thereby performing an inspection (anomaly detection) on the secondary battery 10. Note that corresponding portions in FIG. 5 (the third embodiment) are also hereinafter enclosed in parentheses.

(S101) First, at step S101, charge (initial charge) of the secondary battery 10 to be inspected is started by the power supply 60. Note that, here, as described above, the power supply 60 may be operated manually by the user or, as in the second embodiment, the power supply 60 may be controlled from the anomaly detecting unit 130.

(S102) Next, at S102, the anomaly detecting unit 30 receives an input of the current value I of the secondary battery 10 obtained by the current detecting unit 50 every predetermined time T (301) and, in synchronization, receives an input of the voltage value V of the secondary battery 10 obtained by the voltage detecting unit 40 (302), and stores these values (information) (310).

(S103) Next, at S103, the anomaly detecting unit 30 accumulates the current values I (for each T) to calculate the charged electricity amount (amount of stored electricity Q) (for each T) of the secondary battery 10 (303), and stores the result.

(S104) Next at S104, the anomaly detecting unit 30 determines whether the charged voltage indicated by the amount of stored electricity Q has reached a predetermined voltage. When it is determined that the amount of stored electricity Q has reached the predetermined voltage (Y), the procedure goes to S111, charge (initial charge) ends, and the inspection ends. Note that, here, similarly, the power supply 60 may be operated manually by the user or, as in the second embodiment, the power supply 60 may be controlled from the anomaly detecting unit 130.

(S105) When it is determined that the amount of stored electricity Q has not reached the predetermined voltage (N), the procedure goes to S105, where the anomaly detecting unit 30 calculates a dQ/dV value (for each T), which is a ratio of the changed amount dQ of the amount of stored electricity Q with respect to the changed amount dV of the voltage V (304). In other words, upon initial charge of the secondary battery 10, its amount of stored electricity Q is differentiated with its corresponding voltage V to obtain a dQ/dV value.

(S106) Next, at S106, the anomaly detecting unit 30 determines, by using the dQ/dV value at S105 for the secondary battery 10, whether the state reached any of the feature points A and B on the reference V-dQ/dV curve (K).

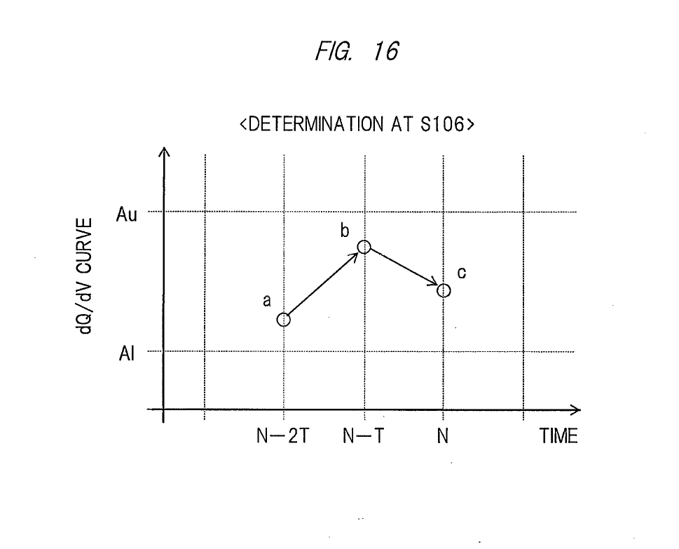

FIG. 16 illustrates an example of the process at S106 as a supplement. For example, as a result of calculating the dQ/dV value for each predetermined time T, when the dQ/dV value increases during a time period from a time N−2T (where N>2T) to a time N−T (point a→b), the dQ/dV value decreases during a time period from the time N−T to a time N (point b→c), and further, the value is within the range of the voltage V where a feature point appears in the reference curve K (FIG. 4) (for example, VAl to VAu), it is determined that the dQ/dV value at the time N−T (point b) is at maximum and the state has reached the feature point (for example, A).

When determining that the state has reached the state corresponding to any of the feature points A and B (maximum points), the anomaly detecting unit 30 stores the dQ/dV value in the state corresponding to any of the feature points A and B (310). When it is determined at S106 described above that the state has not reached any of the feature points A and B (N), the procedure returns to S102, and the processes at S102 to S106 described above are performed.

(S107) When it is determined that the state has reached any of the feature points A and B, the procedure goes to S107, where the anomaly detecting unit 30 calculates a dQ/dV value corresponding to the state of that feature point (305). For example, in the case of S106 described above, the dQ/dV value at N−T is a dQ/dV value corresponding to the feature point (maximum value).

(S108) Thereafter, at S108, the anomaly detecting unit 30 determines whether the dQ/dV value corresponding to the feature point at S107 described above is within the range of the feature points (such as 401 and 411) described above in the reference curve K (306). When the value is within the range (Y), the procedure returns to S102, and the processes at S102 to S108 are performed again.

(S109, S110) When it is determined that the value is out of the range (the value exceeds the range) (N), the procedure goes to S109, where the anomaly detecting unit 30 determines that the secondary battery 10 has a low degree of long-term capacity reliability (long-term capacity reliability cannot be ensured), and detects the secondary battery 10 as anomaly. The procedure then goes to S110, where an anomaly signal indicating that the secondary battery 10 has an anomaly is outputted to the user, thereby prompting the user to exclude the secondary battery 10 (307).

### Fifth Embodiment

Next, an inspection method and an inspection system according to a fifth embodiment will be described with reference to FIG. 15. FIG. 15 illustrates a process flow (a second flow) of detecting a secondary battery 10 with long-term capacity reliability not ensured (anomaly) in the fifth embodiment. The fifth embodiment has a basic structure similar to those of the first embodiment and others (such as FIG. 1). A different structure is such that, the processes of FIG. 15 are performed with program processing at the anomaly detecting unit 30 based on, for example, a user operation, at the time of inspection (S4 of FIG. 5), thereby performing an inspection (anomaly detection) on the secondary battery 10.

In the fifth embodiment, the anomaly detecting unit 30 renders a V-dQ/dV curve (for inspection) based on the dQ/dV actual measurement value at the predetermined time T, calculates a dQ/dV value (for inspection) of a feature point on the curve, and compares the calculated value with the range of the feature points of the reference characteristic curve K, thereby detecting an anomaly.

(S201) At S201, charge (initial charge) of the secondary battery 10 to be inspected is started by the power supply 60.

(S202) At S202, the anomaly detecting unit 30 receives an input of the current value I of the secondary battery 10 obtained by the current detecting unit 50 for each predetermined time T (301) and, in synchronization, receives an input of the voltage value V of the secondary battery 10 obtained by the voltage detecting unit 40 (302), and stores these values (information) (310).

(S203) At S203, the anomaly detecting unit 30 accumulates the current values I (for each T) to calculate the charged electricity amount (amount of stored electricity Q) (for each T) of the secondary battery 10 (303), and stores the result.

(S204) At S204, the anomaly detecting unit 30 determines whether the charged voltage indicated by the amount of stored electricity mount Q has reached a predetermined voltage. When it is determined that the voltage has not reached the predetermined voltage (N), the processes at S202 to S204 are repeated.

(S205) When determining that the voltage has reached the predetermined voltage (Y), the anomaly detecting unit 30 ends the charge (initial charge) at S205, and the procedure goes to S206.

(S206) At S206, the anomaly detecting unit 30 creates a V-dQ/dV curve (for inspection) based on the voltage V of the secondary battery 10 upon initial charge (for each T) and the amount of stored electricity Q (for each T). Specifically, a dQ/dV actual measurement value is calculated from the change quantities dV and dQ for each T (304), and a V-dQ/dV curve is created based on the calculated value.

(S207) At S207, by using the V-dQ/dV curve (for inspection) created at S206 for the secondary battery 10, the anomaly detecting unit 30 calculates (each) feature point from the curve (305). That is, a feature point (a maximum point) corresponding (equivalent) to any of the feature points A and B of the reference cure K is calculated (similar to FIG. 16).

(S208) At S208, the anomaly detecting unit 30 determines whether the dQ/dV actual measurement value of (each of) the feature point (s) is within the range of the dQ/dV values of the feature points A and B in the reference characteristic curve K (FIG. 4) (306). When it is determined that the value is out of the range (N), the procedure goes to S209. When it is determined that all values are within the range (Y), the inspection ends as a result of no anomaly.

(S209, S210) At S209, since the value is out of the range, the anomaly detecting unit 30 detects the secondary battery 10 as anomaly, and outputs an anomaly signal to the user to prompt the user to exclude at S210 (307).

[Effects Etc.]

As has been described above, according to the inspection method and inspection system of the present embodiments, at the stage of manufacturing the secondary battery 10 (FIG. 5), a determination is made by using the characteristics (the curve K) upon initial charge. According to this structure, a secondary battery 10 with ensured long-term capacity reliability (with small degradation in capacity) can be obtained. In other words, it is possible to detect and exclude a secondary battery 10 with a low degree of long-term capacity reliability (with fast degradation in capacity). Also, here, additional inspection process, inspection device, inspection time, and others are not required. Therefore, this structure can be achieved at a low cost. From another point of view, the present embodiments provide technology capable of determining (predicting) long-term capacity performance of the secondary battery 10 at the time of manufacture.

In the foregoing, the invention made by the inventors of the present invention has been concretely described based on the embodiments. However, it is needless to say that the present invention is not limited to the foregoing embodiments and various modifications and alterations can be made within the scope of the present invention.

What is claimed is:

1. A secondary battery inspection system comprising a voltage detecting unit, a current detecting unit, an anomaly detecting unit, and a storage unit,
wherein a first secondary battery to be inspected is connected to the voltage detecting unit, the current detecting unit, and a power supply,
the storage unit stores data of characteristics of a second secondary battery for reference,
the data of the characteristics including information about a V-dQ/dV curve representing a relation between a voltage V and a dQ/dV value, which is a ratio of a changed amount dQ of an amount of stored electricity amount Q calculated from a current I with respect to a changed amount dV of the voltage V upon initial charge of the second secondary battery for reference,
at inspection of the first secondary battery, when initial charge is performed on the first secondary battery from the power supply,
the voltage detecting unit detects a voltage value V of the first secondary battery,
the current detecting unit detects a current value I of the first secondary battery, and
the anomaly detecting unit uses an amount of stored electricity Q calculated from the current value I to calculate a dQ/dV actual measurement value, which is a ratio of a changed amount dQ of the amount of stored electricity Q with respect to a changed amount dV of the voltage value V, compares the dQ/dV actual measurement value and the information about the V-dQ/dV curve to determine whether the dQ/dV actual measurement value corresponds to a feature point on the curve, and detects an anomaly indicating that long-term capacity reliability of the first secondary battery cannot be ensured when the dQ/dV actual measurement value does not correspond to the feature point.

2. The secondary battery inspection system according to claim 1, wherein
the anomaly detecting unit includes:
a current input unit receiving an input of the current value I detected by the current detecting unit;
a voltage input unit receiving an input of the voltage value V detected by the voltage detecting unit;
a charged electric quantity calculating unit calculating the amount of stored electricity Q from the current value I;
a dQ/dV calculating unit calculating the dQ/dV actual measurement value by using the voltage value V and the amount of stored electricity Q;
a dQ/dV feature point calculating unit calculating a feature point equivalent value in the dQ/dV actual measurement value;
an anomaly determining unit comparing the feature point equivalent value in the dQ/dV actual measurement value and the information about the V-dQ/dV curve to determine whether the feature point equivalent value corresponds to the feature point on the curve, and detecting an anomaly indicating that long-term capacity reliability of the first secondary battery cannot be ensured when the feature point equivalent value does not correspond to the feature point; and
an anomaly signal output unit outputting an anomaly signal to a user when the anomaly is detected.

3. The secondary battery inspection system according to claim 1, wherein
a secondary battery with a high capacity retaining ratio as a result of a cycle degradation test and with ensured long-term capacity reliability is used as the second secondary battery for reference,
the data of the characteristics has at least one maximum point as the feature point on the V-dQ/dV curve, and includes information about a range of the voltage value V and a range of the dQ/dV value regarding the feature point,
the anomaly detecting unit compares the dQ/dV actual measurement value and the ranges regarding the feature point of the V-dQ/dV curve at the initial charge in the inspection to determine whether the dQ/dV actual measurement value has reached the feature point on the curve and exceeded the ranges of the feature point, and detects the anomaly when the dQ/dV actual measurement value exceeds the ranges.

4. The secondary battery inspection system according to claim 1, wherein
the anomaly detecting unit starts initial charge at inspection of the first secondary battery,
receives an input of the current value I detected by the current detecting unit and an input of the voltage value V detected by the voltage detecting unit for each predetermined time T in synchronization,
accumulates the current values I to calculate the amount of stored electricity Q from a charged electricity amount,
ends the initial charge and the inspection if a voltage upon initial charge indicated by the amount of stored electricity Q has reached a predetermined voltage,
when the voltage upon initial charge does not reach the predetermined voltage, calculates the dQ/dV actual measurement value for each predetermined time T by using the voltage value V and the amount of stored electricity Q for each predetermined time T,
determines whether the dQ/dV actual measurement value has reached the feature point on the V-dQ/dV curve,
calculates a feature point equivalent value of the dQ/dV actual measurement value when the dQ/dV actual measurement value reaches the feature point, and
determines whether the feature point equivalent value of the dQ/dV actual measurement value exceeds a predetermined range regarding the feature point of the curve and, when the dQ/dV actual measurement value exceeds the predetermined range, detects the anomaly, outputs an anomaly signal to a user, and ends the inspection.

5. The secondary battery inspection system according to claim 1, wherein
the anomaly detecting unit starts initial charge at inspection of the first secondary battery,
receives an input of the current value I detected by the current detecting unit and an input of the voltage value V detected by the voltage detecting unit for each predetermined time T in synchronization,
accumulates the current values I to calculate the amount of stored electricity Q from a charged electricity amount, repeats a detection for each predetermined time T when a voltage upon initial charge indicated by the amount of stored electricity Q has not reached a predetermined voltage,
ends the initial charge when the voltage reaches the predetermined voltage,
calculates the dQ/dV actual measurement value for each predetermined time T by using the voltage value V and the amount of stored electricity Q for each predetermined time T to create a V-dQ/dV curve for inspection,
calculates a feature point equivalent value of the dQ/dV actual measurement value, and
determines whether the feature point equivalent value of the dQ/dV actual measurement value exceeds a predetermined range regarding the feature point of the reference V-dQ/dV curve, detects the anomaly when the feature point equivalent value exceeds the predetermined range, outputs an anomaly signal to a user, and ends the inspection.

6. The secondary battery inspection system according to claim 1, wherein
the anomaly detecting unit is a computer performing program processing.

7. A charger/discharger of a secondary battery comprising a voltage detecting unit, a current detecting unit, an anomaly detecting unit, a storage unit, and a power supply,
wherein a first secondary battery to be inspected is connected to the voltage detecting unit, the current detecting unit, and a power supply,
the storage unit stores data of characteristics of a second secondary battery for reference,
the data of the characteristics including information about a V-dQ/dV curve representing a relation between a voltage V and a dQ/dV value, which is a ratio of a changed amount dQ of an amount of stored electricity amount Q calculated from a current I with respect to a changed amount dV of the voltage V upon initial charge of the second secondary battery for reference,
at inspection of the first secondary battery, when initial charge is performed on the first secondary battery from the power supply by applying a current or a voltage to the first secondary battery,
the voltage detecting unit detects a voltage value V of the first secondary battery,
the current detecting unit detects a current value I of the first secondary battery, and
the anomaly detecting unit uses an amount of stored electricity Q calculated from the current value I to calculate a dQ/dV actual measurement value, which is a ratio of a changed amount dQ of the amount of stored electricity Q with respect to a changed amount dV of the voltage value V, compares the dQ/dV actual measurement value and the information about the V-dQ/dV curve to determine whether the dQ/dV actual measurement value corresponds to a feature point on the curve, and detects an anomaly indicating that long-term capacity reliability of the first secondary battery cannot be ensured when the dQ/dV actual measurement value does not correspond to the feature point.

8. An inspection method of a secondary battery comprising, in an inspecting step of inspecting performance including long-term capacity reliability at the time of manufacturing a first secondary battery:
a first step in which the first secondary battery is connected to a voltage detecting unit, a current detecting unit, and a power supply, initial charge is performed from the power supply on the first secondary battery, the voltage detecting unit detects a voltage value V of the first secondary battery and the current detecting unit detects a current value I of the first secondary battery; and
a second step in which, at the initial charge, the voltage value V and the current value I are used to detect an anomaly indicating that long-term capacity reliability of the first secondary battery cannot be ensured,
the second step using a V-dQ/dV curve as data of characteristics of a second secondary battery for reference for anomaly detection, the V-dQ/dV curve representing a relation between a voltage V and a dQ/dV value, which is a ratio of a changed amount dQ of an amount of stored electricity Q calculated from the current I with respect to a changed amount dV of the voltage V, at the initial charge of the second secondary battery, and
the second step calculating a dQ/dV actual measurement value, which is the ratio of the changed amount dQ of the amount of stored electricity Q with respect to the changed amount dV of the voltage V, with using the amount of stored electricity Q calculated from the current I, comparing the dQ/dV actual measurement value and the V-dQ/dV curve to determine whether the dQ/dV actual measurement value corresponds to a feature point on the curve, and detecting an anomaly indicating that long-term capacity reliability of the first secondary battery cannot be ensured when the dQ/dV actual measurement value does not correspond to the feature point.

9. The secondary battery inspection method according to claim 8, wherein
the inspecting step includes the steps of:
(1) starting the initial charge from the power supply on the first secondary battery;
(2) detecting the voltage value V and the current value I of the first secondary battery for each predetermined time in synchronization;
(3) accumulating the current values I to calculate the amount of stored electricity Q;
(4) determining whether a voltage at the initial charge indicated by the amount of stored electricity Q has reached a predetermined voltage and ending the initial charge when the voltage has reached the predetermined voltage;
(5) calculating the dQ/dV actual measurement value when the voltage has not reached the predetermined voltage;
(6) determining whether the dQ/dV actual measurement value has reached the feature point on the reference V-dQ/dV curve and repeating the steps (2) to (5) when the dQ/dV actual measurement value has not reached the feature point;
(7) calculating the feature point equivalent value of the dQ/dV actual measurement value when the dQ/dV actual measurement value has reached the feature point;
(8) comparing the feature point equivalent value of the dQ/dV actual measurement value and the range regarding the feature point on the V-dQ/dV curve of the characteristics to determine whether the feature point equivalent value is in the range, and repeating the steps (2) to (7) when the feature point equivalent value is in the range; and
(9) detecting the anomaly if the feature point equivalent value is not in the range and outputting an anomaly signal to a user.

10. The secondary battery inspection method according to claim 8, wherein
the inspecting step includes the steps of:
(1) starting the initial charge from the power supply on the first secondary battery;
(2) detecting the voltage value V and the current value I of the first secondary battery for each predetermined time in synchronization;
(3) accumulating the current values I to calculate the amount of stored electricity Q;
(4) determining whether a voltage at the initial charge indicated by the amount of stored electricity Q has reached a predetermined voltage and repeating the steps (2) to (4) when the voltage has not reached the predetermined voltage;
(5) ending the initial charge if the voltage has reached the predetermined voltage;
(6) calculating the dQ/dV actual measurement value to create a V-dQ/dV curve for inspection;
(7) calculating one or more feature point equivalent values regarding the dQ/dV actual measurement value from the V-dQ/dV curve for inspection;
(8) comparing feature point equivalent values of the dQ/dV actual measurement value and the range regarding the feature point on the reference V-dQ/dV curve to determine whether all of the feature point equivalent value are in a range regarding the feature point on the reference V-dQ/dV curve; and
(9) detecting the anomaly when the feature point equivalent values are not in the range and outputting an anomaly signal to the user.
